(19) United States
(12) Patent Application Publication
(10) Pub. No.: US 2017/0092533 A1
(43) Pub. Date: Mar. 30, 2017

(54) SELECTIVE SILICON DIOXIDE DEPOSITION USING PHOSPHONIC ACID SELF ASSEMBLED MONOLAYERS AS NUCLEATION INHIBITOR

(71) Applicant: APPLIED MATERIALS, INC., Santa Clara, CA (US)

(72) Inventors: Tapash Chakraborty, Mumbai (IN); Mark Saly, Santa Clara, CA (US); Rana Howlader, Sivasagar (IN); Eswaranand Venkatasubramanian, Chennai (IN); Prerna Sonthalia Goradia, Mumbai (IN); Robert Jan Visser, Menlo Park, CA (US); David Thompson, San Jose, CA (US)

(21) Appl. No.: 14/957,380

(22) Filed: Dec. 2, 2015

Related U.S. Application Data
(60) Provisional application No. 62/234,461, filed on Sep. 29, 2015.

(51) Int. Cl. H01L 21/768; H01L 21/321; H01L 21/02

(52) U.S. Cl. CPC H01L 21/76802; H01L 21/02164; H01L 21/0226; H01L 21/02307; H01L 21/76877; H01L 21/7684; H01L 21/3212; H01L 21/0217; H01L 21/02167

(57) ABSTRACT

Methods of selectively depositing a patterned layer on exposed dielectric material but not on exposed metal surfaces are described. A self-assembled monolayer (SAM) is deposited using phosphonic acids. Molecules of the self-assembled monolayer include a head moiety and a tail moiety, the head moiety forming a bond with the exposed metal portion and the tail moiety extending away from the patterned substrate and reducing the deposition rate of the patterned layer above the exposed metal portion relative to the deposition rate of the patterned layer above the exposed dielectric portion. A dielectric layer is subsequently deposited by atomic layer deposition (ALD) which cannot initiate in regions covered with the SAM in embodiments.

### CROSS-REFERENCES TO RELATED APPLICATIONS

This application claims the benefit of U.S. Prov. Pat. App. No. 62/234,461 filed Sep. 29, 2015, and titled “SELECTIVE SILICON DIOXIDE DEPOSITION USING PHOSPHONIC ACID SELF ASSEMBLED MONOLAYERS AS NUCLEATION INHIBITOR” by Chakraborty et al., which is hereby incorporated in its entirety herein by reference for all purposes.

### FIELD

Embodiments described herein relate to selectively depositing dielectric materials.

### BACKGROUND

Semiconductor device geometries have dramatically decreased in size since their introduction several decades ago. Modern semiconductor fabrication equipment is routinely used to produce devices having geometries as small as 14 nm and less, and new equipment designs are continually being developed and implemented to produce devices with even smaller geometries. The high expense of photolithography operations motivates manufacturers to try to develop simple self-aligned processes which double, triple or quadruple the pattern density relative to the printed linewidth. These self-aligned processes may involve depositing a conformal spacer layer over a core to create sidewalls with double the pitch of the cores.

In addition to extending the use of excimer light sources, manufacturing flows would simplify with the development of self-aligned processes which remove a photolithography step as well.

### SUMMARY

Methods of selectively depositing a patterned layer on exposed dielectric material but not on exposed metal surfaces are described. A self-assembled monolayer (SAM) is deposited using phosphonic acids. Molecules of the self-assembled monolayer include a head moiety and a tail moiety, the head moiety forming a bond with the exposed metal portion and the tail moiety extending away from the patterned substrate and reducing the deposition rate of the patterned layer above the exposed metal portion relative to the deposition rate of the patterned layer above the exposed dielectric portion. A dielectric layer is subsequently deposited by atomic layer deposition (ALD) which cannot initiate in regions covered with the SAM in embodiments.

Embodiments described herein include methods of forming a patterned layer on a patterned substrate. The methods include selectively forming a patterned layer on the patterned substrate. A deposition rate of the patterned layer on an exposed dielectric portion of the patterned substrate is at least one hundred times greater than a deposition rate of the patterned layer on an exposed metal portion of the patterned substrate. The patterned layer is patterned after formation and without application of photolithography.

The patterned layer may be patterned after formation without applying any intervening photolithography or etching operations. The patterned layer may be formed by repeated and alternating exposure to a first precursor and a second precursor. The patterned layer may be formed by a surface chemical reaction mechanism.

Embodiments described herein include methods of forming a patterned layer on a patterned substrate. The methods include providing a patterned substrate having an exposed dielectric portion and an exposed metal portion. The exposed metal portion is electrically conducting. The methods further include exposing the patterned substrate to phosphonic acid. The methods further include forming a self-assembled monolayer on the exposed metal portion but not on the exposed dielectric portion. The methods further include placing the patterned substrate in a substrate processing region. The methods further include forming the patterned layer by: (1) flowing a first precursor into the substrate processing region, (2) removing unused portions of the first precursor from the substrate processing region (3) flowing a second precursor into the substrate processing region, and (4) removing unused portions of the second precursor from the substrate processing region. The methods further include repeating (1)-(4) an integral number of times to form a thickness of patterned layer.

The substrate processing region may be plasma-free during operations (1)-(4). A head moiety of a molecule of the phosphonic acid includes a PO₃H group. A tail moiety of a molecule of the phosphonic acid may include a perfluorinated alkyl group having more than 5 carbon atoms covalently bonded in a chain. A tail moiety of a molecule of the phosphonic acid may include an aromatic ring. A tail moiety of a molecule of the phosphonic acid may include an alkyl group having more than 12 carbon atoms covalently bonded in a chain. A thickness of the patterned layer may exceed 10 nm. The methods may further include removing the self-assembled monolayer after forming the thickness of patterned layer to reexpose the exposed metal portion.

Embodiments described herein include methods of forming a patterned layer on a patterned substrate. The methods include forming a patterned dielectric layer on the patterned substrate. The patterned dielectric layer has a gap. The methods further include forming an electrically conducting layer in the gap of the patterned dielectric layer. The methods further include chemical mechanical polishing the electrically conducting layer to remove metal disposed above the gap resulting in an exposed dielectric portion and an exposed metal portion. The methods further include exposing the patterned substrate to phosphonic acid. The methods further include forming a self-assembled monolayer on the exposed metal portion but not on the exposed dielectric portion. The methods further include placing the patterned substrate in a substrate processing region. The methods further include forming the patterned layer by repeated alternating exposure to a first precursor and a second precursor. A deposition rate of the patterned layer above the exposed dielectric portion is at least one hundred times greater than a deposition rate of the patterned layer above the exposed metal portion. The substrate processing region is plasma-free during the repeated alternating exposure.

The patterned dielectric layer may be SiO, SiN or SiCN. The exposed metal portion may include at least one of copper, nickel, cobalt, halfnium, tantalum and tungsten. The exposed metal portion may consist of a transition metal or a combination of transition metals. The exposed metal portion may consist of one or a combination of copper, nickel, cobalt, halfnium, tantalum and tungsten. Each molecule of the self-assembled monolayer may include a head moiety and a tail moiety, the head moiety forming a bond with the exposed metal portion and the tail moiety extending away from the patterned substrate and reducing the deposition rate of the patterned layer above the exposed metal portion relative to the deposition rate of the patterned layer above the exposed dielectric portion. The patterned layer may be a dielectric layer or a metal layer (an electrically conducting layer).

To better understand the nature and advantages of the present invention, reference should be made to the following description and the accompanying figures. It is to be understood, however, that each of the figures is provided for the purpose of illustration only and is not intended as a definition of the limits of the scope of the present invention.

### DESCRIPTION OF THE DRAWINGS

A further understanding of the nature and advantages of the disclosed technology may be realized by reference to the remaining portions of the specification and the drawings.

FIGS. 1A, 1B, 1C and 1D are cross-sectional views during a selective deposition process according to embodiments.

FIG. 2 is method of selectively depositing material on exposed dielectric on a patterned substrate according to embodiments.

FIGS. 3A, 3B, 3C and 3D are graphical illustrations of the preferential deposition of a SAM on an exposed metal portion of a patterned substrate according to embodiments.

FIGS. 4A and 4B are schematic views of substrate processing equipment according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Methods of selectively depositing a patterned layer on exposed dielectric material but not on exposed metal surfaces are described. A self-assembled monolayer (SAM) is deposited using phosphonic acids. Molecules of the self-assembled monolayer include a head moiety and a tail moiety, the head moiety forming a bond with the exposed metal portion and the tail moiety extending away from the patterned substrate and reducing the deposition rate of the patterned layer above the exposed metal portion relative to the deposition rate of the patterned layer above the exposed dielectric portion. A dielectric layer is subsequently deposited by atomic layer deposition (ALD) which cannot initiate in regions covered with the SAM in embodiments.

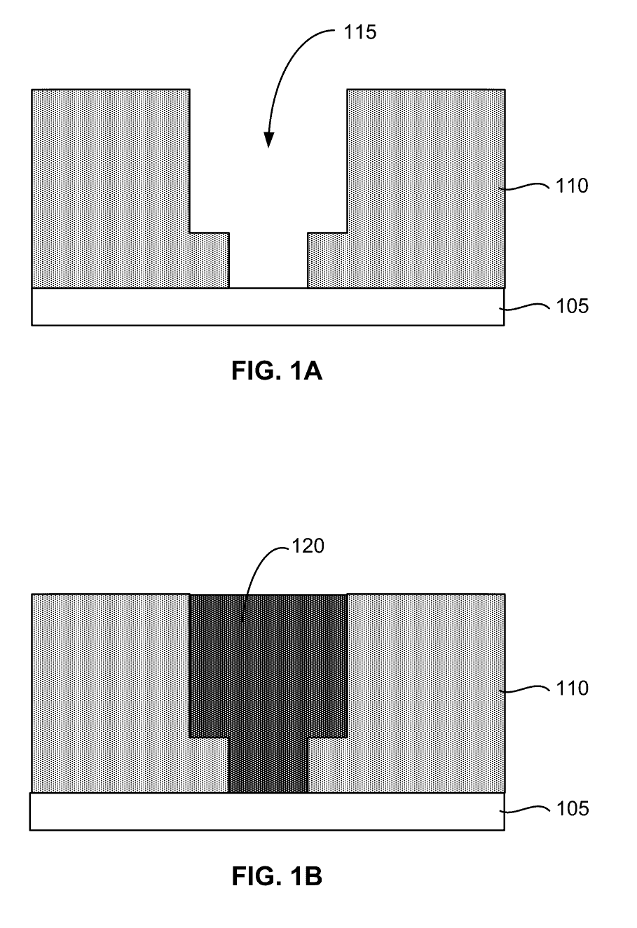

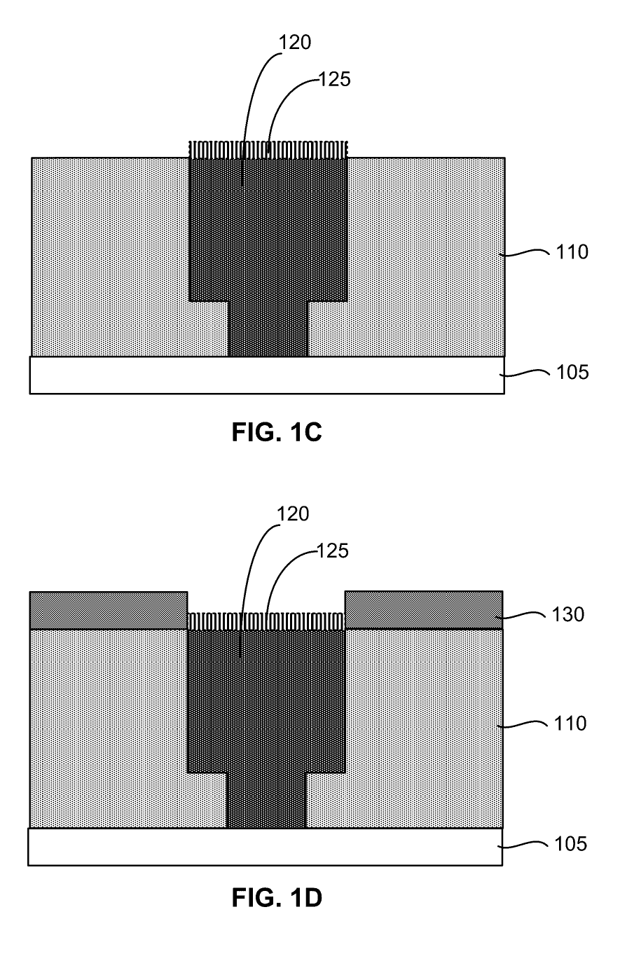

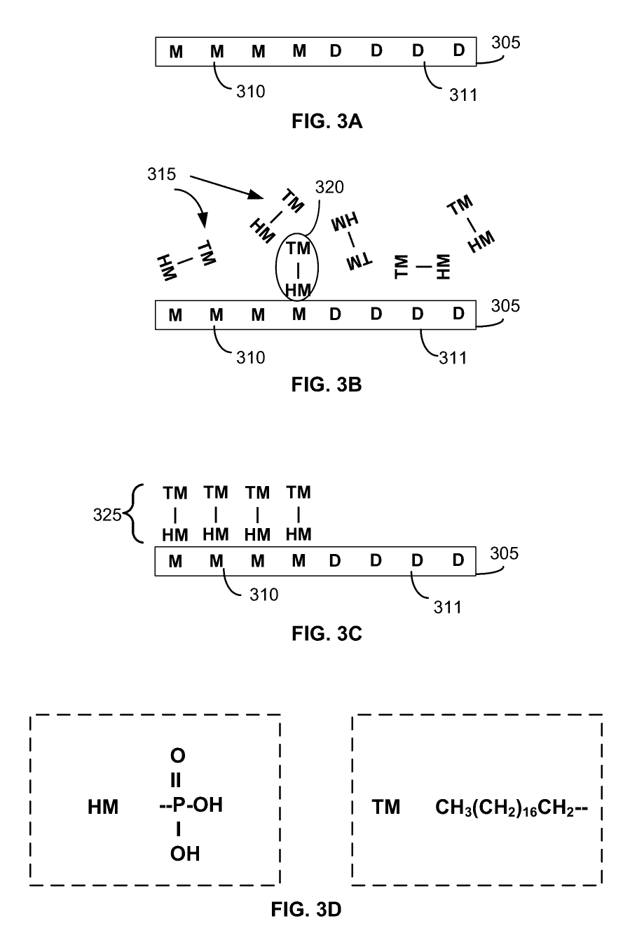

In embodiments, methods of preferentially forming a self-assembled monolayer (SAM) on exposed metal portions rather than exposed dielectric portions which also present on a patterned substrate are described. Dielectric is then formed selectively on the exposed dielecric portions. FIGS. 1A-1D are cross-sectional views during an exemplary selective deposition process according to embodiments. The methods described herein may be generally applied to a wide variety of pattern architectures but the example shown in FIGS. 1A-1D is a dual-damascene process often used to form copper interconnects and vias in a single deposition. An underlying layer 105 has a patterned layer of dielectric 110 having two distinct patterns formed which will collectively be referred to in the example as gap 115. Dielectric 110 may be a low-k dielectric such as Black Diamond, which is available from Applied Materials, Santa Clara, Calif. The Black Diamond™ film is an organo-silane film with a lower dielectric constant (e.g., about 3.5 or less) than conventional spacer materials like silicon oxides and nitrides. However, the techniques described herein work on any exposed dielectric according to embodiments. As illustrated in FIG. 1B, a metal 120, such as copper, may be formed in trench 115 perhaps by electroplating. A self-assembled monolayer (SAM) 125 is selectively formed using particular phosphonic acid molecules having a head moiety of (PO₃H as shown in FIG. 3D) and a tail moiety of a relatively long carbon chain (e.g. an alkyl group) as specified herein. The head moiety has been found to promote preferential covalent adhesion onto exposed metal but not onto exposed dielectric elsewhere on the patterned substrate. FIGS. 1C and 1D are for illustration only and the actual thickness of SAM 125 is not shown to scale. A selectively deposited film 130 is then formed preferentially on dielectric 110. The tail moiety of the phosphonic acid molecules presented herein have been found to discourage deposition of selectively deposited film 130 onto SAM 125 which means no further deposition occurs above metal 120 according to embodiments.

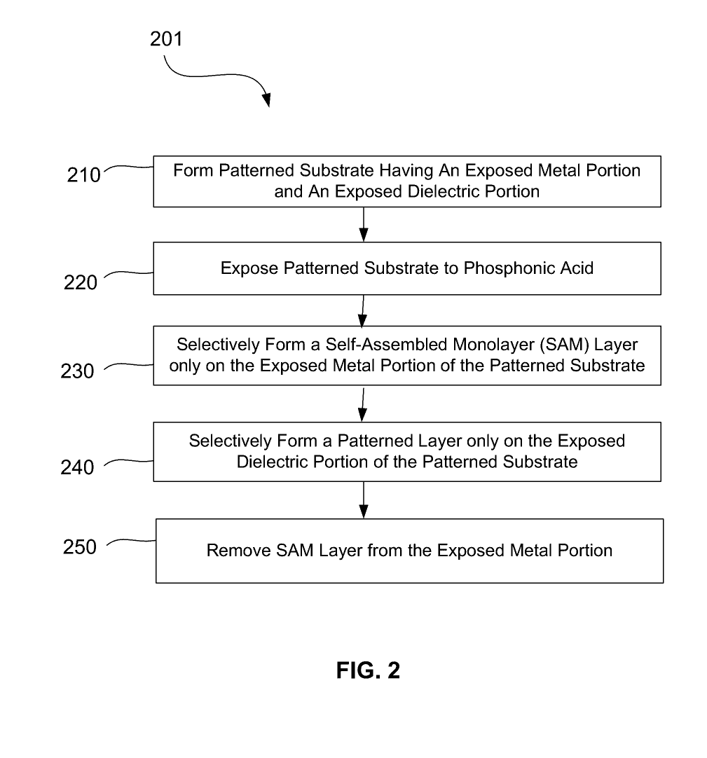

To better understand and appreciate the embodiments presented herein, reference is now made to FIG. 2 which is a method 201 of selectively depositing material on exposed dielectric on a patterned substrate according to embodiments. Reference will concurrently be made to FIGS. 3A-3D which are graphical illustrations of the preferential deposition of a SAM on an exposed metal portion of a patterned substrate according to some embodiments. A patterned substrate having an exposed metal portion and an exposed dielectric portion is formed in operation 210 and shown in FIG. 3A. FIG. 3A illustrates a patterned substrate 305 having both metal bonding sites 310 (denoted “M”) and dielectric sites 311 (denoted “D”) on exposed surfaces of the patterned substrate. Each metal bonding site 310 is designated with an “M” which represents a location where molecules may form chemical bonds with metal atoms disposed on the outer surface of patterned substrate 305. In some embodiments “M” may be a transition metal or an alloy of metals as detailed herein. In the example of method 201, “M” represents a copper atom at the surface of the exposed metal portion.

The patterned substrate is exposed to phosphonic acid in operation 220. A SAM is deposited on metal bonding sites 310 of the exposed metal portion of the patterned substrate 305 (operation 230). SAM molecules 315 may diffuse within a liquid solution placed in contact with the exposed metal portion and the exposed dielectric portion of the patterned substrate. Each SAM molecule 315 may comprise a head moiety “HM” at a first end of the molecule and a tail moiety “TM” at a distal end of the molecule. These head and tail moieties may be referred to as “functional groups”. The HM is PO₃H as shown in the left portion of FIG. 3D and the TM may be a covalently bonded chain of carbon (an alkyl chain) as shown in the right portion of FIG. 3D. The chain may consist only of covalently bonded carbons, in embodiments, with hydrogens and/or fluorine atom terminating the otherwise dangling bonds of the carbons. The TM of the phosphonic acid may include an aromatic ring according to embodiments.

The head moiety of diffusing SAM molecules 315 may occasionally form a covalent chemical bond between the SAM molecule 315 and the metal bonding site 310, perhaps by forming a alkyl-—O-M bond with the surface. A SAM molecule 320 is shown covalently bonded to a metal bonding site 310 by way of the head moiety “HM” in FIG. 3B. The local chemical interaction between metal atom bonding site 310 and head moiety of bonded molecule 320 may immobilize the metal atoms “M” and inhibit metal ionization and diffusion. Note that the chemisorbed SAM molecule 320 is missing a hydrogen atom to make way for the O-M bond but will still be referred to as a SAM molecule in the adsorbed state for simplicity. The SAM is formed from SAM molecule formed by the chemisorption of “head functional groups” onto a substrate from either the vapor or liquid phase followed by a general alignment of “tail functional groups” distal from metal bonding sites 310. The tail moiety may not chemically bond to either the metal bonding sites 310 or the dielectric sites 311 according to embodiments. FIG. 3B illustrates a plurality of SAM molecules 315 during a deposition process where the SAM molecules are randomly oriented and proximate patterned substrate 305. The plurality of SAM molecules 315 may self-align wherein only the head moiety may bond with exposed metal portion containing metal bonding sites 315 of patterned substrate 305. Once all metal atom bonding sites 310 in metal layer 305 are bonded with SAM molecules 315, the bonding process may cease, becoming a self-limiting process.

The head moiety of SAM molecule 315 may be selected to bind with the metal bonding sites 310 in patterned substrate 305 but not to dielectric sites 311 during operation 230. Adsorbed SAM molecules 320 may accumulate on the exposed metal portion but may not accumulate on the exposed dielectric portion according to embodiments. The completed self-assembled monolayer SAM 325 may ultimately cover the exposed metal portion and leave the exposed dielectric portion uncovered, in embodiments, as shown in FIG. 3C.

In operation 240, a patterned layer is deposited on the patterned substrate but only on the portions of the patterned substrate which are not covered with the SAM. The patterned layer may be deposited by an alternating exposure to a first then a second precursor which ensure the growth occurs by way of surface chemical reactions rather than gas-phase chemical reactions. The patterned layer may also be formed to a selectable thickness by repeated and alternating exposure to the first precursor and the second precursor. An unused portion of the first precursor may be removed from the substrate processing region prior to introducing the second precursor into the substrate processing region. Analogously, an unused portion of the second precursor may be removed from the substrate processing region prior to reintroducing the first precursor into the substrate processing region. Operation 240 may be carried out while the patterned substrate is resident in a plasma-free substrate processing region to preserve the integrity of the SAM according to embodiments.

The SAM layer is removed during operation 250 to reexpose the exposed metal portion which had been temporarily covered with the SAM. Selective deposition method 201 forms a patterned substrate without the typical requirement of depositing photoresist, performing photolithography and etching an initially conformal layer. In embodiments, no photoresist is deposited, no lithography is performed and no etching is performed between operation 210 and selectively forming the patterned layer on the exposed dielectric portion of the patterned substrate (operation 240). Stated another way the patterned layer may be patterned after formation without applying any intervening lithography or etching operations. The portion of the patterned layer above the exposed dielectric portion may have a thickness which exceeds 10 nm, exceeds 20 nm or exceeds 30 nm in embodiments. The thickness of the portion of the patterned layer above the exposed metal portion (before or after operation 250) may be immeasurably small by the most sensitive means, may be less than 0.3 nm, less than 0.2 nm or less than 0.1 nm according to embodiments.

The deposition rate of the patterned layer over the SAM/metal is much less than with the deposition rate of the patterned layer over the exposed dielectric portion (which is not covered by the self-assembled monolayer). The deposition rate of the patterned layer over the SAM/metal may be reduced by the presence of the SAM and the deposition rate may be much less than if the SAM were not present. In embodiments, the deposition rate over the exposed dielectric portion may be more than one hundred times, more than one hundred fifty times or more than two hundred times the growth rate over the SAM (over the exposed metal portion). The deposition rate over an exposed metal portion uncovered by a SAM may be more than one hundred times, more than one hundred fifty times or more than two hundred times the growth rate over a SAM covered otherwise-exposed metal portion.

The precursors used to deposit the self-assembled monolayers herein may be described as SAM molecules especially when tail moieties (TM) and head moieties (HM) and minute interactions between the precursors and the patterned substrate are being described. The precursors may be a phosphonic acid which include a HM as shown in the right portion of FIG. 3D. The SAM molecules may be one or more of octylphosphonic acid (CH₃(CH₂)₆CH₂—P(O)(OH)₂), perfluorooctylphosphonic acid (CF₃(CF₂)₅CH₂—CH₂—P(O)(OH)₂), octadecylphosphonic acid (CH₃(CH₂)₁₆CH₂—P(O)(OH)₂), decyl phosphonic acid, mesityl phosphonic acid, cyclohexyl phosphonic acid, hexyl phosphonic acid or butyl phosphonic acid according to embodiments.

The tail moiety (TM) functions to prevent or discourage nucleation of the patterned layer during the alternating exposure to the first precursor and the second precursor. The tail moiety of the SAM molecule of the phosphonic acid may include a perfluorinated alkyl group having more than 5 carbon atoms, more than 6 carbon atoms or more than 7 carbon atoms covalently bonded to one another in a chain according to embodiments. The presence of the larger fluorine atoms in lieu of the much smaller hydrogen atoms appears to discourage nucleation of the patterned layer for smaller carbon chains. The tail moiety of the SAM molecule of the phosphonic acid may include an alkyl group having more than 12 carbon atoms, more than 14 carbon atoms, or more than 16 carbon atoms, covalently bonded in a chain in embodiments.

The exposed metal portion may be electrically conducting according to embodiments. The exposed metal portion may comprise at least one of copper, nickel, cobalt, halfnium, tantalum and tungsten in embodiments. The exposed metal portion may consist of one or more of copper, nickel, cobalt, halfnium, tantalum and tungsten according to embodiments. Copper, nickel, cobalt, halfnium, tantalum and tungsten are examples of “metal” elements for all materials described herein and indicate that a material consisting only of the “metal” element will electrically conducting to a degree suitable for use in electrical wiring. According to embodiments. The exposed metal portion may consist of a transition metal or a combination of transition metals in embodiments.

The exposed dielectric portion may be a metal oxide and comprise a metal element and oxygen. The exposed dielectric portion may comprise silicon and further comprise one or more of oxygen, nitrogen and carbon according to embodiments. The exposed dielectric portion may be one of silicon oxide (SiO), silicon oxynitride (SiON), silicon nitride (SiN), silicon carbon nitride (SiCN) in embodiments. The exposed dielectric portion may consist of silicon and oxygen, silicon oxygen and nitrogen, silicon and nitrogen or silicon carbon and nitrogen according to embodiments.

The patterned layer may nucleate by a surface chemical reaction mechanism to ensure the SAM can interfere with nucleation on the exposed metal portion. The patterned layer may comprise silicon and further comprise one or more of oxygen, nitrogen and carbon according to embodiments. The patterned layer may be one of silicon oxide (SiO), silicon oxynitride (SiON), silicon nitride (SiN), silicon carbon nitride (SiCN) in embodiments. The patterned layer may consist of silicon and oxygen, silicon oxygen and nitrogen, silicon and nitrogen or silicon carbon and nitrogen according to embodiments. The patterned layer may be a dielectric layer. In embodiments, the patterned layer may be a metal layer which is electrically conducting or may be a metal-containing layer such as a metal oxide.

In one embodiment SAM 325 is thermally stable and can withstand thermal processing at relatively high temperatures up to 400° C., up to 450° C. or even up to 500° C. A temperature of the patterned substrate is less than 400° C., less than 450° C. or less than 500° C. during each of the operation of forming the self-assembled monolayer and forming the patterned layer according to embodiments.

In the methods disclosed herein, the patterned substrate may include a gap in the patterned dielectric layer. An electrically conducting layer may be formed in the gap of the patterned dielectric layer. Chemical mechanical polishing may then be performed to remove the portion of the electrically conducting layer located above the gap resulting in an exposed dielectric portion and an exposed metal portion (within the gap in the patterned dielectric layer). This is an exemplary process for creating the exposed metal portion and the exposed dielectric portion described in the examples presented herein. The exemplary process is often referred to as a “damascene” process or a “dual-damascene” process depending on the complexity of the gap in the patterned dielectric layer.

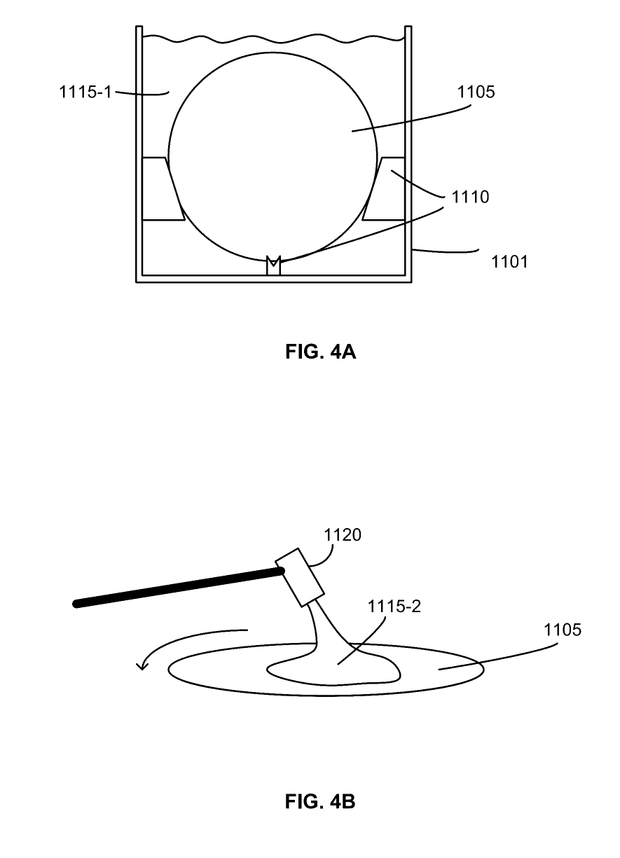

FIGS. 4A and 4B are schematic views of substrate processing equipment according to embodiments. FIG. 4A shows hardware used to expose substrate 1105 to a dilute phosphonic acid liquid solution 1115-1 in a tank 1101. Substrate 1105 may be lowered into solution 1115-1 using a robot and may be supported by substrate supports 1110 during processing. FIG. 4B shows alternative hardware which spins substrate 1105 while pouring dilute phosphonic acid liquid solution 1115-2 from a dispenser 1120 across the top surface of the substrate.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon oxide” of the patterned substrate is predominantly SiO₂ but may include concentrations of other elemental constituents such as, e.g., nitrogen, hydrogen and carbon. In some embodiments, silicon oxide portions described herein consist of or consist essentially of silicon and oxygen. Exposed “silicon nitride” or “SiN” of the patterned substrate is predominantly Si₃N₄ but may include concentrations of other elemental constituents such as, e.g., oxygen, hydrogen and carbon. In some embodiments, silicon nitride portions described herein consist of or consist essentially of silicon and nitrogen. Other silicon-containing dielectrics may be used for growth of the patterned layer upon or the patterned layer itself. For example, exposed “silicon carbon nitride” or “SiCN” of the patterned substrate is predominantly silicon carbon and nitrogen but may include concentrations of other elemental constituents such as, e.g., oxygen and hydrogen. In some embodiments, silicon carbon nitride portions described herein consist of or consist essentially of silicon, carbon and nitrogen.

Exposed “silicon oxycarbide” or “SiOC” of the patterned substrate is predominantly silicon carbon and oxygen but may include concentrations of other elemental constituents such as, e.g., carbon and hydrogen. In some embodiments, silicon oxycarbide portions described herein consist of or consist essentially of silicon, carbon and oxygen.

Exposed “metal” of the patterned substrate is predominantly metal atoms but may include concentrations of other elemental constituents such as, e.g., oxygen, nitrogen, hydrogen and carbon. A metal atom is defined as forming a good electrical conductor when a condensed matter material is formed consisting only of the metal atom. In some embodiments, exposed metal portions described herein consist of or consist essentially of one or more metal atoms so the definition includes a variety of alloys. The metal atom may be a transition metal (e.g. one of copper, nickel, cobalt, halfnium, tantalum and tungsten). The exposed dielectric may be a metal oxide comprising a metal atom. The selection of metal atoms may be the same as the definition given above. For example, exposed “tantalum oxide” or “TaO” of the patterned substrate is predominantly tantalum and oxygen but may include concentrations of other elemental constituents such as, e.g., nitrogen, hydrogen and carbon. In some embodiments, exposed tantalum oxide portions may consist of or consist essentially of tantalum and oxygen. The definition of other metal oxides (e.g. TiO, CuO) will now be understood by this example. The patterned layer (patterned during formation and without requiring photolithography) may be any of the metal materials or dielectric materials, just defined, as long the reaction proceeds by a surface reaction mechanism rather than a gas phase mechanism which may be fully inhibited by the SAM layer. The formation process may proceed by repeated and alternating exposure to a first precursor and a second precursor to ensure that the mechanism of formation is a surface reaction mechanism.

The term “gap” is used throughout with no implication that the geometry has a large horizontal aspect ratio. Viewed from above the surface, gaps may appear circular, oval, polygonal, rectangular, or a variety of other shapes. A “trench” is a long gap. A trench may be in the shape of a moat around an island of material whose aspect ratio is the length or circumference of the moat divided by the width of the moat. The term “via” is used to refer to a low aspect ratio trench (as viewed from above) which may or may not be filled with metal to form a vertical electrical connection. As used herein, a conformal deposition process refers to a generally uniform removal of material on a surface in the same shape as the surface, i.e., the surface of the deposited layer and the underlying surface are generally parallel. A person having ordinary skill in the art will recognize that the conformal layer likely cannot be 100% conformal and thus the term “generally” allows for acceptable tolerances.

The term “precursor” is used to refer to any process gas which takes part in a reaction to either remove material from or deposit material onto a surface. The phrase “inert gas” refers to any gas which does not form chemical bonds during processing even when incorporated into a film. Exemplary inert gases include noble gases but may include other gases so long as no covalent bonds are formed when (typically) trace amounts are trapped in a film.

Having disclosed several embodiments, it will be recognized by those of skill in the art that various modifications, alternative constructions, and equivalents may be used without departing from the spirit of the disclosed embodiments. Additionally, a number of well-known processes and elements have not been described to avoid unnecessarily obscuring the present embodiments. Accordingly, the above description should not be taken as limiting the scope of the claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the claims, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming a patterned layer on a patterned substrate, the method comprising:
selectively forming a patterned layer on the patterned substrate, wherein a deposition rate of the patterned layer on an exposed dielectric portion of the patterned substrate is at least one hundred times greater than a deposition rate of the patterned layer on an exposed metal portion of the patterned substrate, wherein the patterned layer is patterned after formation and without application of photolithography.

2. The method of claim 1 wherein the patterned layer is patterned after formation without applying any intervening photolithography or etching operations.

3. The method of claim 1 wherein the patterned layer is formed by repeated and alternating exposure to a first precursor and a second precursor.

4. The method of claim 1 wherein the patterned layer is formed by a surface chemical reaction mechanism.

5. A method of forming a patterned layer on a patterned substrate, the method comprising:
providing a patterned substrate having an exposed dielectric portion and an exposed metal portion, wherein the exposed metal portion is electrically conducting;
exposing the patterned substrate to phosphonic acid;
forming a self-assembled monolayer on the exposed metal portion but not on the exposed dielectric portion;
placing the patterned substrate in a substrate processing region;
forming the patterned layer by:
(1) flowing a first precursor into the substrate processing region,
(2) removing unused portions of the first precursor from the substrate processing region
(3) flowing a second precursor into the substrate processing region, and
(4) removing unused portions of the second precursor from the substrate processing region; and
repeating (1)-(4) an integral number of times to form a thickness of patterned layer.

6. The method of claim 5 wherein the substrate processing region is plasma-free during operations (1)-(4).

7. The method of claim 5 wherein a head moiety of a molecule of the phosphonic acid includes a PO₃H group.

8. The method of claim 5 wherein a tail moiety of a molecule of the phosphonic acid includes a perfluorinated alkyl group having more than 5 carbon atoms covalently bonded in a chain.

9. The method of claim 5 wherein a tail moiety of a molecule of the phosphonic acid includes an aromatic ring.

10. The method of claim 5 wherein a tail moiety of a molecule of the phosphonic acid includes an alkyl group having more than 12 carbon atoms covalently bonded in a chain.

11. The method of claim 5 wherein a thickness of the patterned layer exceeds 10 nm.

12. The method of claim 5 further comprising removing the self-assembled monolayer after forming the thickness of patterned layer to reexpose the exposed metal portion.

13. A method of forming a patterned layer on a patterned substrate, the method comprising:
forming a patterned dielectric layer on the patterned substrate, wherein the patterned dielectric layer has a gap;
forming an electrically conducting layer in the gap of the patterned dielectric layer;
chemical mechanical polishing the electrically conducting layer to remove metal disposed above the gap resulting in an exposed dielectric portion and an exposed metal portion;
exposing the patterned substrate to phosphonic acid;
forming a self-assembled monolayer on the exposed metal portion but not on the exposed dielectric portion;
placing the patterned substrate in a substrate processing region; and
forming the patterned layer by repeated alternating exposure to a first precursor and a second precursor, wherein a deposition rate of the patterned layer above the exposed dielectric portion is at least one hundred times greater than a deposition rate of the patterned layer above the exposed metal portion, and wherein the substrate processing region is plasma-free during the repeated alternating exposure.

14. The method of claim 13 wherein the patterned dielectric layer comprises one of SiO, SiN, SiCN.

15. The method of claim 13 wherein the exposed metal portion comprises at least one of copper, nickel, cobalt, hafnium, tantalum and tungsten.

16. The method of claim 13 wherein the exposed metal portion consists of a transition metal or a combination of transition metals.

17. The method of claim 13 wherein the exposed metal portion consists of one or more of copper, nickel, cobalt, hafnium, tantalum and tungsten.

18. The method of claim 13 wherein each molecule of the self-assembled monolayer includes a head moiety and a tail moiety, the head moiety forming a bond with the exposed metal portion and the tail moiety extending away from the patterned substrate and reducing the deposition rate of the patterned layer above the exposed metal portion relative to the deposition rate of the patterned layer above the exposed dielectric portion.

19. The method of claim 13 wherein the patterned layer is a dielectric layer.

20. The method of claim 13 wherein the patterned layer is a metal layer.

21. The method of claim 13 wherein a temperature of the patterned substrate is less than 400° C. during each of the operation of forming the self-assembled monolayer and forming the patterned layer.
